(19) United States
(12) Patent Application Publication
(10) Pub. No.: US 2016/0268282 A1
(43) Pub. Date: Sep. 15, 2016

(54) SEMICONDUCTOR MEMORY DEVICE AND METHOD FOR MANUFACTURING SAME

(71) Applicant: Kabushiki Kaisha Toshiba, Minato-ku (JP)

(72) Inventor: Shota ISHIBASHI, Yokkaichi (JP)

(73) Assignee: Kabushiki Kaisha Toshiba, Minato-ku (JP)

(21) Appl. No.: 14/751,627

(22) Filed: Jun. 26, 2015

Related U.S. Application Data
(60) Provisional application No. 62/132,926, filed on Mar. 13, 2015.

(51) Int. Cl. H01L 27/115; H01L 29/06

(52) U.S. Cl. CPC H01L 27/11568; H01L 27/11582; H01L 29/0649

(57) ABSTRACT

According to one embodiment, a semiconductor memory device includes a substrate; a conductive layer provided on the substrate; a stacked body provided on the conductive layer and including a plurality of electrode layers stacked to be separated from each other; a semiconductor pillar portion provided in the stacked body and extending in a stacking direction of the stacked body; an interconnect portion provided in the stacked body, extending in the stacking direction and a first direction crossing the stacking direction, and including a lower surface; a semiconductor portion provided in the conductive layer via an insulating film relative to the conductive layer, provided integrally with the semiconductor pillar portion; and an insulating portion. The semiconductor portion includes: a first portion; a second portion; and a third portion. The insulating portion is provided between the first portion and the second portion.

### CROSS-REFERENCE TO RELATED APPLICATIONS

This application is based upon and claims the benefit of priority from U.S. Provisional Patent Application 62/132,926 field on Mar. 13, 2015; the entire contents of which are incorporated herein by reference.

### FIELD

Embodiments described herein relate generally to a semiconductor memory device and a method for manufacturing same.

### BACKGROUND

A memory device having a three-dimensional structure has been proposed, in which memory holes are formed in a stacked body including a plurality of electrode layers that function as control gates in memory cells and are stacked via an insulating layer, and a silicon body serving as a channel is provided on a side wall of the memory hole via a charge storage film.

The memory hole and a contact connected to the memory hole are formed in the stacked body of the three-dimensional device by, for example, RIE (Reactive Ion Etching) method. At this time, in accordance with the miniaturization of the three-dimensional device, the difficulty level of processing can become high.

### BRIEF DESCRIPTION OF THE DRAWINGS

FIG. 1 is a schematic perspective view of a memory cell array of an embodiment;

FIG. 2A is a schematic sectional view of the memory cell array of the embodiment and FIG. 2B is a schematic plan view of the memory cell array of the embodiment;

FIG. 3A and FIG. 3B are enlarged schematic sectional views of part of the memory cell array of the embodiment;

FIG. 4 is an enlarged schematic sectional view of a part of the columnar portion of the embodiment; and

FIG. 5A to FIG. 17B are schematic views showing a method for manufacturing the semiconductor memory device of the embodiment.

### DETAILED DESCRIPTION

According to one embodiment, a semiconductor memory device includes a substrate; a conductive layer provided on the substrate; a stacked body provided on the conductive layer and including a plurality of electrode layers stacked to be separated from each other; a semiconductor pillar portion provided in the stacked body and extending in a stacking direction of the stacked body; an interconnect portion provided in the stacked body, extending in the stacking direction and a first direction crossing the stacking direction, and including a lower surface; a semiconductor portion provided relative to the conductive layer via an insulating film in the conductive layer, provided integrally with the semiconductor pillar portion, and extending in the first direction and a second direction crossing the stacking direction and the first direction; and an insulating portion. The semiconductor portion includes: a first portion provided relative to the stacked body via the conductive layer and the insulating film; a second portion provided between the first portion and the substrate and separated from the first portion in the stacking direction; and a third portion having a maximum thickness, in the stacking direction, thicker than a maximum thickness of the first portion and ticker than a maximum thickness of the second portion, and being in contact with the lower surface. The insulating portion is provided between the first portion and the second portion.

Embodiments are described below with reference to the drawings. Note that in the drawings, the same components are denoted by the same reference numerals and signs.

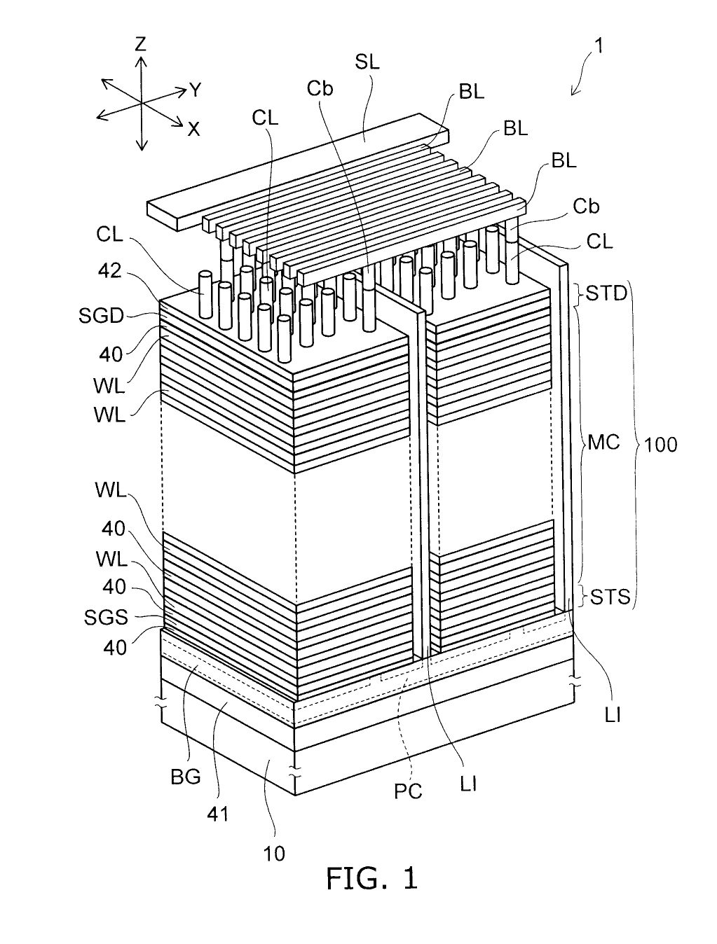

First, a configuration of a semiconductor memory device of an embodiment will be described with reference to FIG. 1 to FIG. 3B.

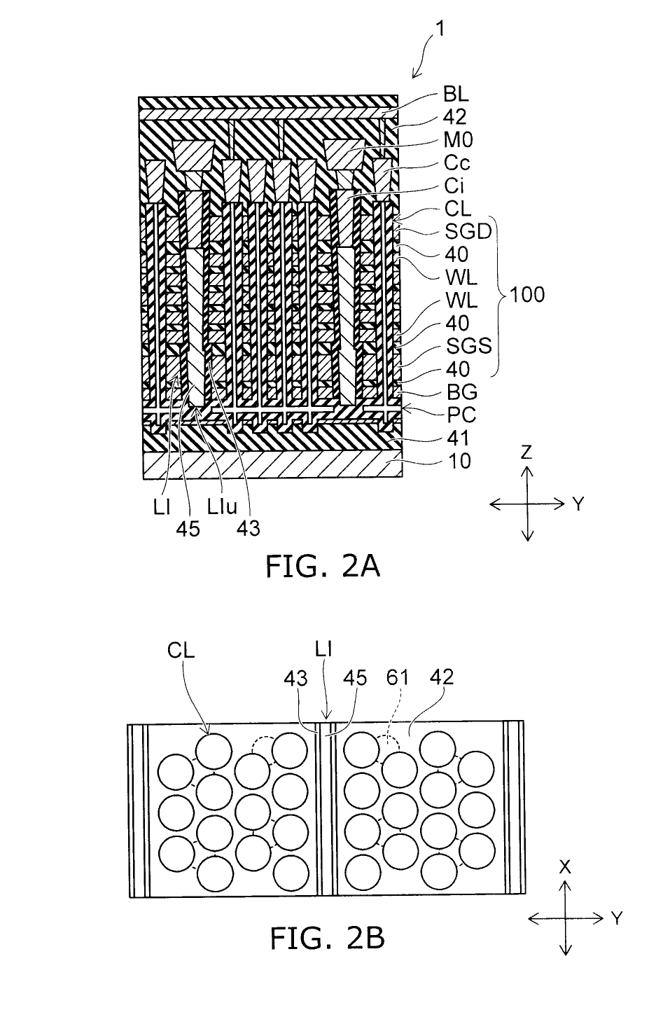

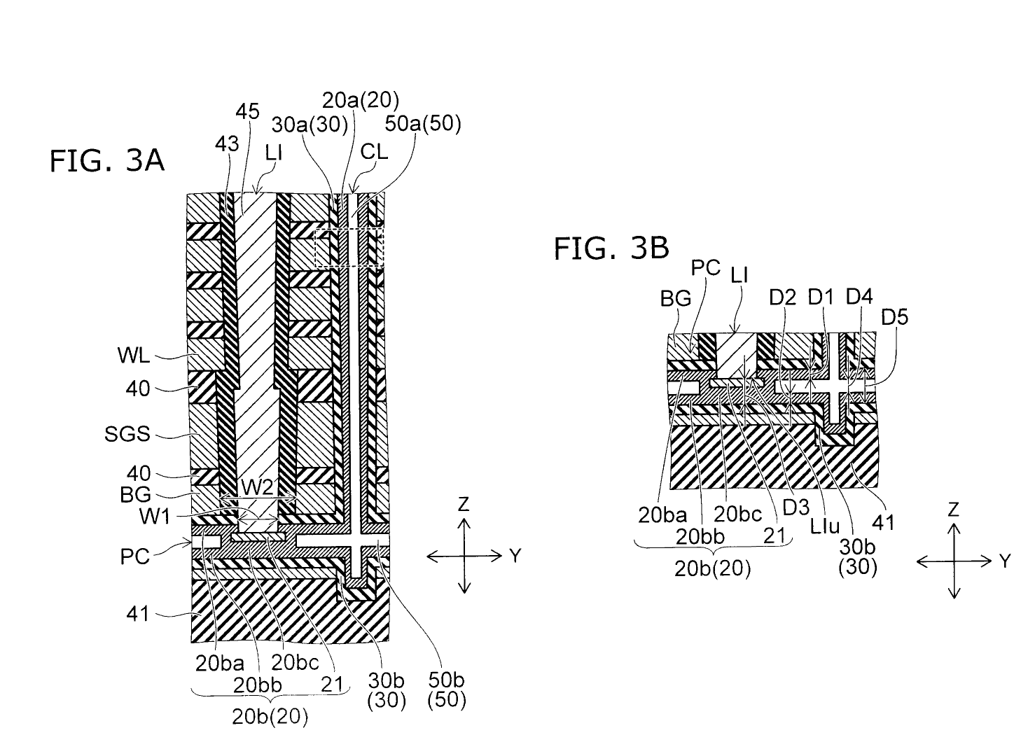

FIG. 1 is a schematic perspective view of a memory cell array 1 of the embodiment, FIG. 2A is a schematic sectional view showing the memory cell array 1 of the embodiment, FIG. 2B is a schematic plan view on columnar portions CL of the embodiment, and FIG. 3A and FIG. 3B are enlarged schematic sectional views of part of the memory cell array 1 of the embodiment.

In FIG. 1, two directions parallel to a major surface of a substrate 10 and perpendicular to each other are an X-direction (first direction) and a Y-direction (second direction), and a direction perpendicular to both the X-direction and the Y-direction is a Z-direction (stacking direction).

As shown in FIG. 1 and FIG. 2A, the memory cell array 1 includes the substrate 10, a back gate BG (conductive layer), a stacked body 100, the plurality of columnar portions CL, an interconnect portion LI, and upper layer interconnections BL and SL. FIG. 1 shows bit lines BL and a source layer SL as the upper layer interconnections.

The back gate BG is provided on the substrate 10 via an insulating layer 41. The stacked body 100 is provided on the back gate BG via an insulating layer 40.

The stacked body 100 includes a plurality of electrode layers WL, a plurality of insulating layers 40, a source side select gate SGS and a drain side select gate SGD. The plurality of electrode layers WL is separately stacked each other, and the plurality of insulating layers 40 is provided between the plurality of electrode layers WL.

The plurality of electrode layers WL and the plurality of insulating layers 40 are, for example, alternately stacked one layer by one layer. Incidentally, the number of the electrode layers WL shown in the drawing is an example, and the number of the electrode layers WL is arbitrary.

The source side select gate SGS is provided in the undermost layer of the stacked body 100. The drain side select gate SGD is provided in the uppermost layer of the stacked body 100.

The plurality of electrode layers WL contains, for example, metal. The plurality of electrode layers WL is, for example, silicon layers containing silicon as a main component. The silicon layers are doped with impurities for giving conductivity, for example, boron. The plurality of electrode layers WL may include metal silicide parts (material containing metal and silicon). Incidentally, the back gate BG, the source side select gate SGS and the drain side select gate SGD contain the same material as that of the plurality of electrode layers WL, or may contain, for example, different material.

The insulating layers 40 and 41 are, for example, insulating films mainly containing silicon oxide. The insulating layer 40 may include, for example, a gap (air gap).

Each of the thickness of the drain side select gate SGD and the thickness of the source side select gate SGS is thicker than the thickness of one electrode layer WL, and for example, the plurality of layers may be provided. For example, each of the thickness of the drain side select gate SGD and the thickness of the source side select gate SGS may be equal to or thinner than the thickness of one electrode layer WL. In that case, the plurality of layers may be provided similarly to the above. Incidentally, the “thickness” here is a thickness in the stacking direction (Z-direction) of the stacked body 100.

The columnar portions CL extending in the Z-direction are provided in the stacked body 100. The columnar portion CL is formed into, for example, a cylindrical shape or an elliptic cylindrical shape. As shown in FIG. 2B, the plurality of columnar portions CL is arranged in, for example, hound's-tooth check pattern. Alternatively, the plurality of columnar portions CL may be arranged in square lattice pattern along the X-direction and the Y-direction.

The columnar portion CL includes a channel body 20 (semiconductor portion), a memory film 30 and a core insulating portion 50 as shown in FIG. 3A. The memory film 30 is provided between the stacked body 100 and the channel body 20. The core insulating portion 50 is provided inside the channel body 20. The channel body 20 may have, for example, a columnar shape. For example, the core insulating portion 50 may not be provided inside the channel body 20.

The channel body 20 is, for example, a silicon film containing silicon as a main component. The core insulating portion 50 includes, for example, a silicon oxide film and may include an air gap.

The stacked body 100 is provided with the interconnect portion LI extending in the X-direction and the Z-direction in the stacked body 100. The interconnect portion LI is sandwiched between the stacked bodies 100. An insulating film 43 is provided on a side wall of the interconnect portion LI, and a conductive film 45 is provided inside the insulating film 43. The insulating film 43 and the conductive film 45 extend in the X-direction and the Z-direction similarly to the interconnect portion LI. The conductive film 45 is made of at least one of, for example, tungsten, titanium and titanium nitride. The insulating film 43 is, for example, a silicon oxide film.

The interconnect portion LI includes a lower surface LIu. The lower surface LIu is electrically connected to the columnar portion CL via a coupling portion PC provided in the back gate BG. An upper end of the interconnect portion LI is connected to the source layer SL provided on the stacked body 100.

The coupling portion PC is provided integrally with the columnar portion CL, and extends in the X-direction and the Y-direction in the back gate BG. For example, the plurality of columnar portions CL is provided integrally with the coupling portion PC. Incidentally, “provided integrally” means that a part of the material used for the columnar portion CL extends up to the coupling portion PC.

The coupling portion PC includes a memory film 30b (insulating film) provided integrally with the columnar portion CL, a channel body 20b (semiconductor portion) and a core insulating portion 50b (insulating portion). The memory film 30b, the channel body 20b and the core insulating portion 50b extend in the X-direction and the Y-direction in the back gate BG. The details of the configuration of the coupling portion PC will be described later.

The plurality of bit lines BL (for example, metal films) is provided on the stacked body 100. The plurality of bit lines BL is separated from each other in the X-direction and extends in the Y-direction.

An upper end portion of the channel body 20 is connected to the bit line BL via a contact portion Cc. In the plurality of columnar portions CL, the plurality of channel bodies 20 selected one by one from the respective regions separated in the Y-direction is connected to one common bit line BL.

A drain side select transistor STD is provided on an upper end portion of the columnar portion CL, and a source side select transistor STS is provided on a lower end portion.

A memory cell MC, the drain side select transistor STD and the source side select transistor STS are vertical transistors in which current flows in the stacking direction (Z-direction) of the stacked body 100.

The respective select gates SGD and SGS function as gate electrodes (control gates) of the respective select transistors STD and STS. The memory film 30 functioning as a gate insulating film of each of the select transistors STD and STS is provided between each of the select gates SGD and SGS and the channel body 20.

the plurality memory cells MC using the respective electrode layers WL as control gates is provided between the drain side select transistor STD and the source side select transistor STS.

The plurality memory cells MC, the drain side select transistor STD and the source side select transistor STS are connected in series via the channel body 20, and constitutes one memory string. Such memory strings are arranged in a plane direction parallel to the X-Y plane in, for example, hound's-tooth check pattern, so that the plurality memory cells MC is three-dimensionally provided in the X-direction, the Y-direction and the Z-direction.

The semiconductor memory device of the embodiment can freely erase and write data electrically, and can hold memory contents even when the power supply is turned off.

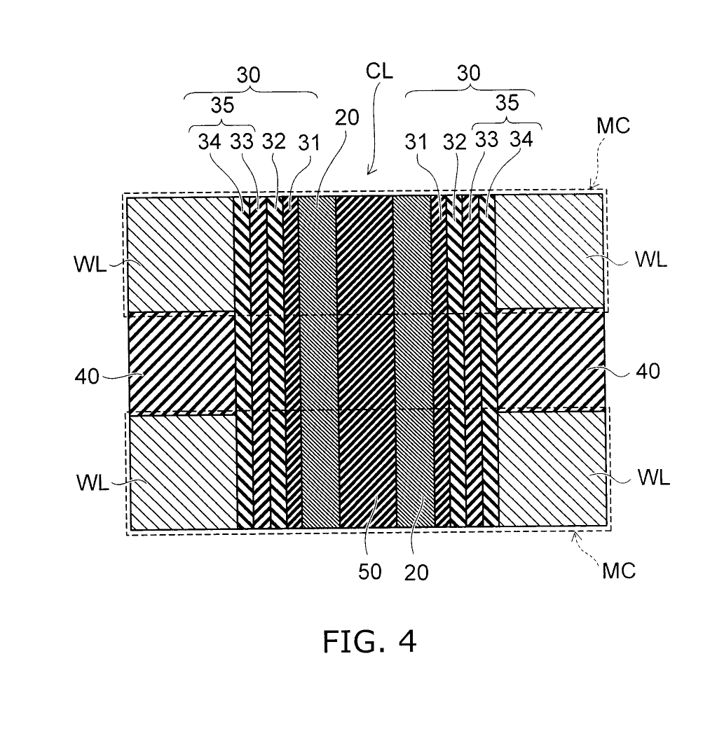

Next, an example of the memory cell MC of the embodiment will be described with reference to FIG. 4.

FIG. 4 is an enlarged schematic sectional view of a portion of the columnar portion CL of the embodiment.

The memory film 30 includes, for example, a block insulating film 35, a charge storage film 32 and a tunnel insulating film 31. The block insulating film 35 contacts the electrode layer WL, and the tunnel insulating film 31 contacts the channel body 20. The charge storage film 32 is provided between the block insulating film 35 and the tunnel insulating film 31.

The block insulating film 35 includes a block film 33 and a cap film 34. The block film 33 is provided between the cap film 34 and the charge storage film 32. The cap film 34 is provided in contact with the electrode layer WL.

The block film 33 is, for example, a silicon oxide film. A film having a dielectric constant higher than that of the block film 33 is used as the cap film 34, the cap film 34 includes, for example, at least one of a silicon nitride film and an aluminum oxide film.

The charge storage film 32 includes many trap sites for trapping charges, and is, for example, a silicon nitride film.

The tunnel insulating film 31 is, for example, a silicon oxide film. Alternatively, the tunnel insulating film 31 may be a stacked film (ONO film) having a structure in which a silicon nitride film is sandwiched between a pair of silicon oxide films.

The memory cell MC is of, for example, a charge-trap type. The channel body 20 functions as a channel in the memory cell MC, and the electrode layer WL functions as the control gate of the memory cell MC. The charge storage film 32 functions as a data memory layer to store charge injected from the channel body 20. That is, the memory cell MC having a structure in which the control gate surrounds the periphery of the channel is formed in a crossing portion between the channel body 20 and the electrode layer WL.

The block insulating film 35 prevents charge stored in the charge storage film 32 from diffusing into the electrode layer WL. The cap film 34 of the block insulating film 35 is provided in contact with the electrode layer WL, so that back-tunneling electron injected from the electrode layer WL at erasing can be suppressed. That is, when the stacked film of the silicon oxide film and the silicon nitride film is used as the block insulating film 35, the charge blocking property can be enhanced.

The tunnel insulating film 31 become a potential barrier when charge is injected into the charge storage film 32 from the channel body 20 or when charge stored in the charge storage film 32 diffuses into the channel body 20. For example, when the ONO film is used as the tunnel insulating film 31, an erasing operation can be performed in low electric field as compared with the single layer of the silicon oxide film.

Next, a configuration of the coupling portion PC of the embodiment will be described with reference to FIG. 3A and FIG. 3B.

As shown in FIG. 3A and FIG. 3B, the memory film 30b is provided on the wall surface of the coupling portion PC, and contacts the back gate BG. The memory film 30b is separated from the lower surface LIu. The memory film 30b is separated in the Y-direction via the interconnect portion LI.

The channel body 20b is provided relative to the back gate BG via the memory film 30b. The channel body 20b contacts the lower surface LIu. The channel body 20b is continuously provided in the X-direction and the Y-direction. The channel body 20b is provided between the interconnect portion LI and the core insulating portion 50b.

The core insulating portion 50b is provided inside the channel body 20b. The core insulating portion 50b is separated from the lower surface LIu and the memory film 30b.

The channel body 20b includes a first portion 20ba, a second portion 20bb and a third portion 20bc.

The first portion 20ba is provided relative to the stacked body 100 via the back gate BG and the memory film 30b. The second portion 20bb is provided between the first portion 20ba and the substrate 10, and is provided relative to the substrate 10 via the back gate BG and the memory film 30b. The core insulating portion 50b is provided between the second portion 20bb and the first portion 20ba. The second portion 20bb is separated from the first portion 20ba.

The third portion 20bc is provided between the lower surface LIu and the memory film 30b. The third portion 20bc contacts the lower surface LIu, the first portion 20ba, the second portion 20bb and the core insulating portion 50b. That is, the first portion 20ba and the second portion 20bb are continuously provided in the Y-direction via the third portion 20bc. Besides, the core insulating portion 50b is separated in the Y-direction via the third portion 20bc.

The channel body 20b includes an impurity layer 21 provided in the third portion 20bc. The impurity layer 21 contacts the lower surface LIu. The impurity layer 21 may extend in one of the first portion 20ba and the second portion 20bb.

As shown in FIG. 3A, for example, in the Y-direction, a maximum length W2 of the interconnect portion LI is larger than a maximum length W1 between the memory films 30b separated via the interconnect portion LI.

As shown in FIG. 3B, in the Z-direction, a maximum thickness D3 of the third portion 20bc is thicker than a maximum thickness D1 of the first portion 20ba and is thicker than a maximum thickness D2 of the second portion 20bb.

Besides, the channel body 20b has a maximum thickness D5 including that of the core insulating portion 50b in the Z-direction. That is, the maximum thickness D5 is the maximum thickness of the sum of the thickness D1 of the first portion 20ba, the thickness D2 of the second portion 20bb, and a thickness D4 of the core insulating portion 50b, which are arranged in the Z-direction. The maximum thickness D5 is thicker than the maximum thickness D3 of the third portion.

Incidentally, the maximum thickness D1 of the first portion 20ba and the maximum thickness D2 of the second portion 20bb are equal to a maximum distance between the core insulating portion 50b and the memory film 30b. Besides, the maximum thickness D3 of the third portion 20bc is equal to a maximum distance between the lower surface LIu and the memory film 30b.

The impurity layer 21 includes an impurity, and the impurity concentration of the impurity layer 21 is higher than the impurity concentration of the channel body 20. For example, boron is used as the impurity contained in the impurity layer 21, and is expressed by, for example, the number per unit area (atm/cm³). The interconnect portion LI is electrically connected to the channel body 20 via the impurity layer 21.

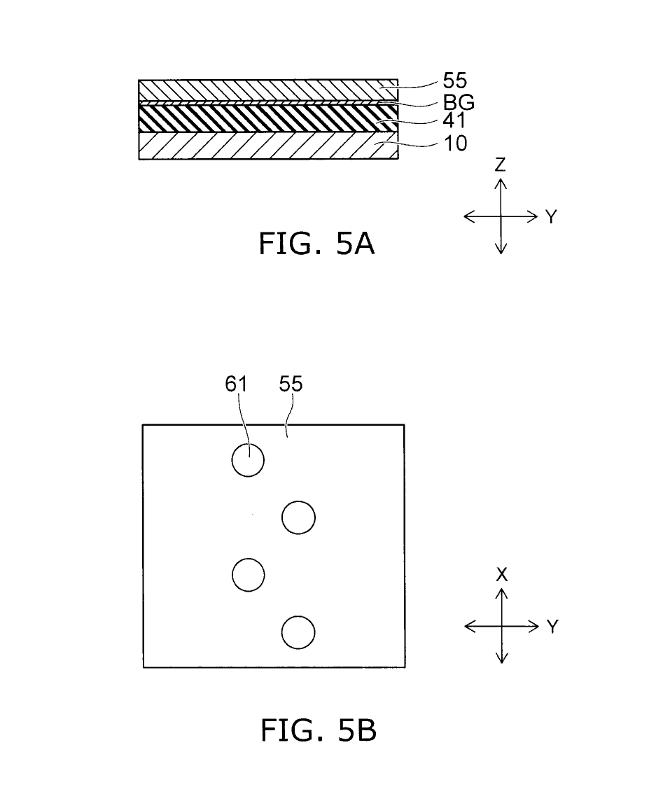

Next, a method for manufacturing the semiconductor memory device of the embodiment will be described with reference to FIG. 5A to FIG. 17B.

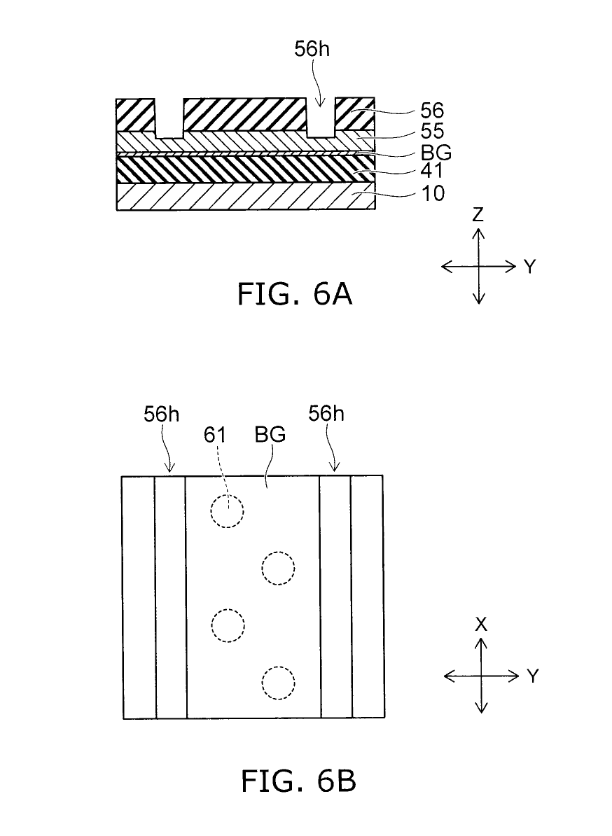

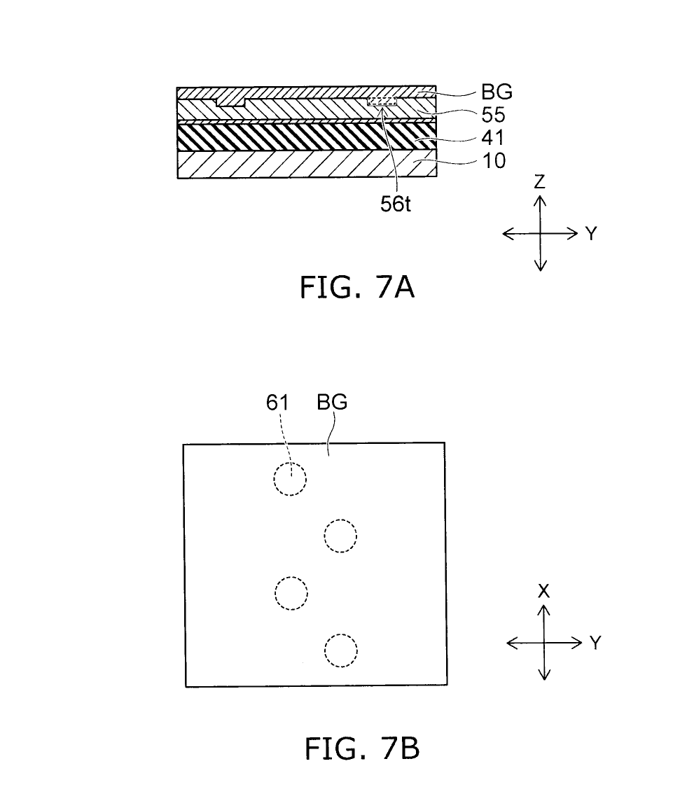

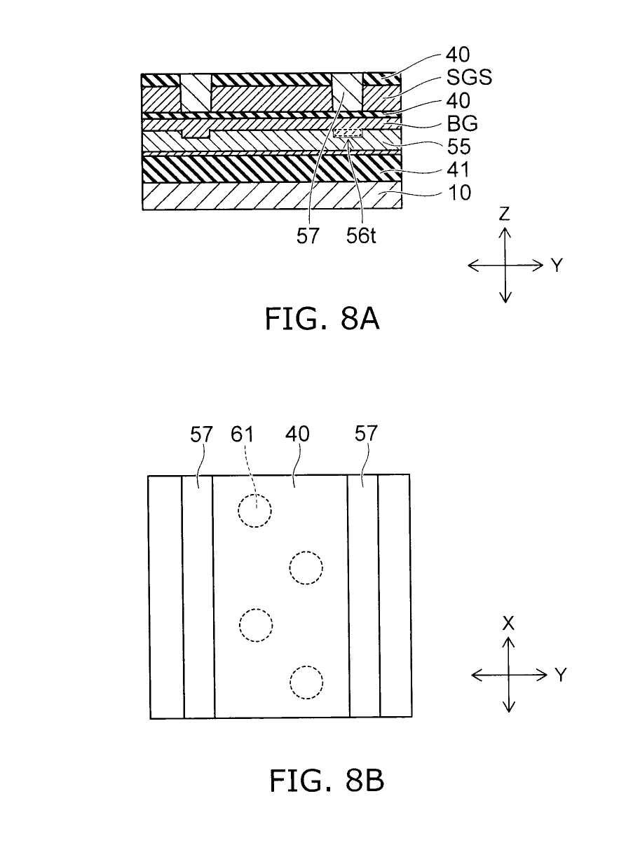

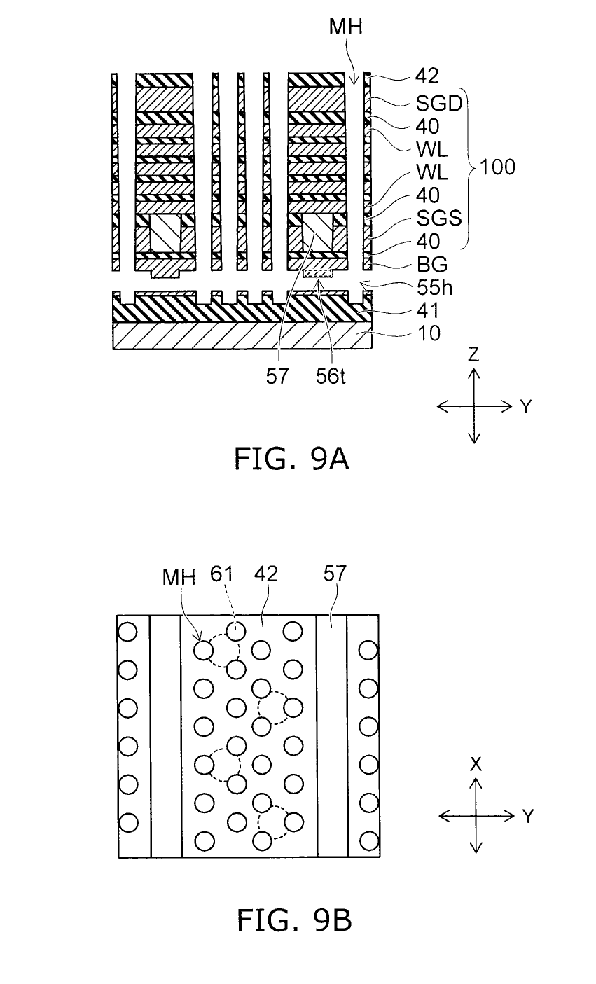

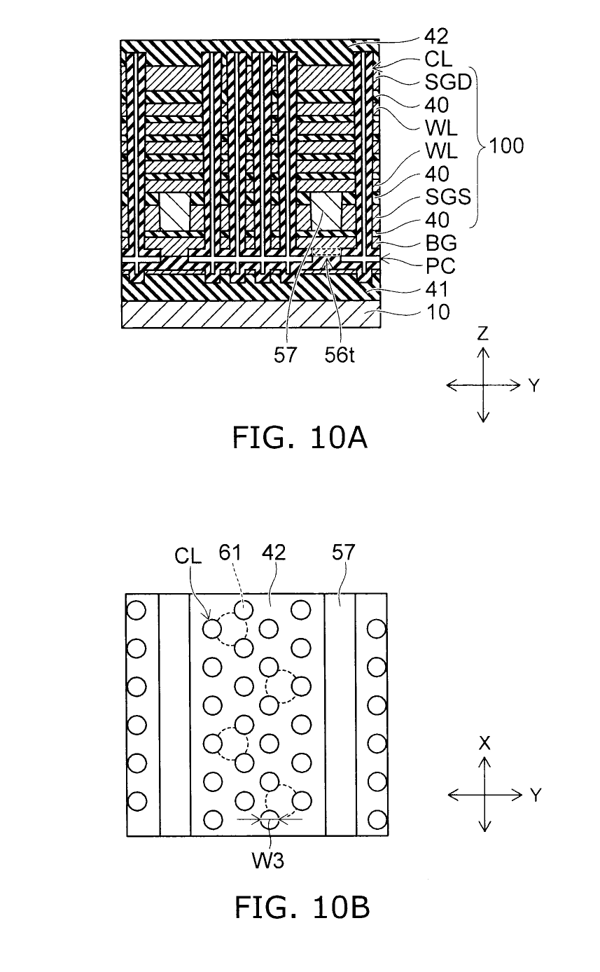

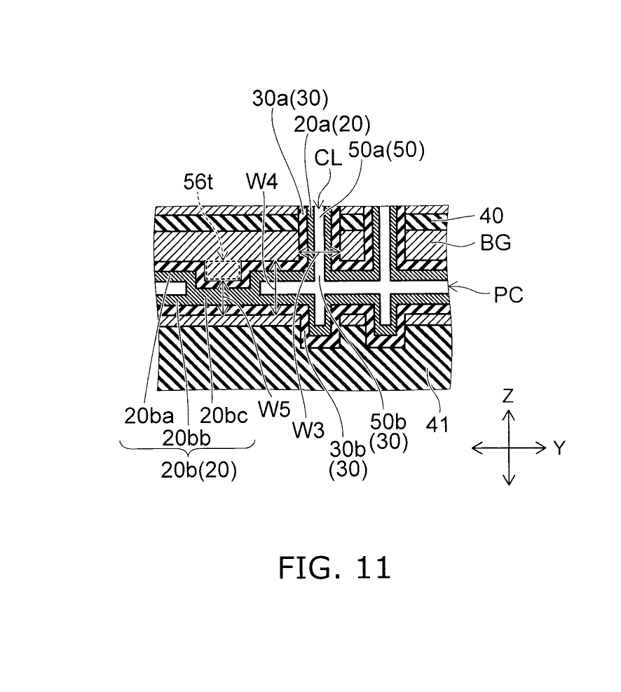

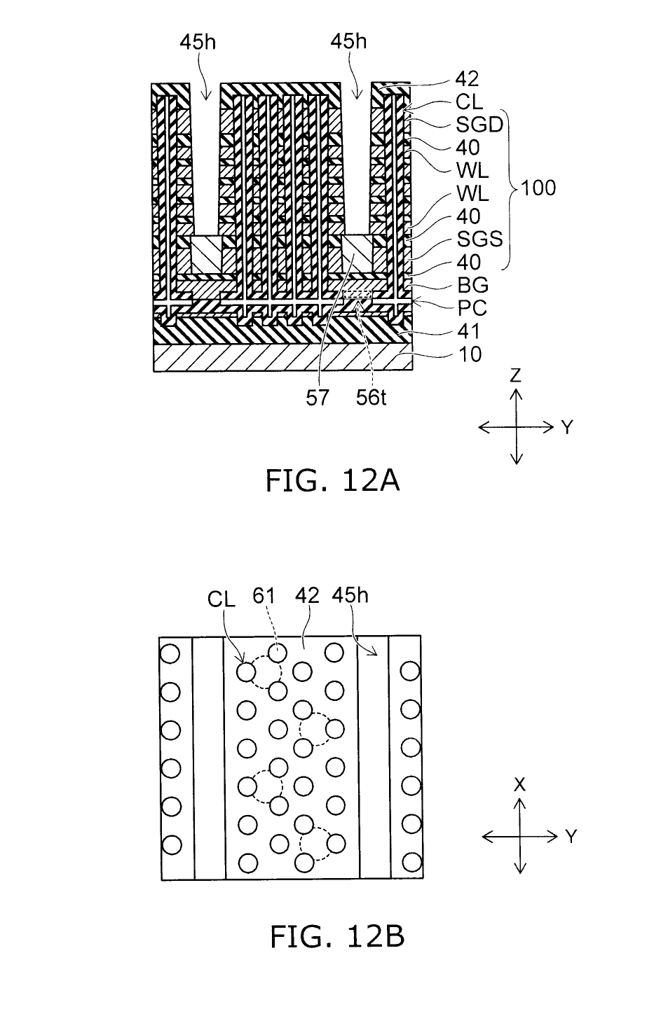

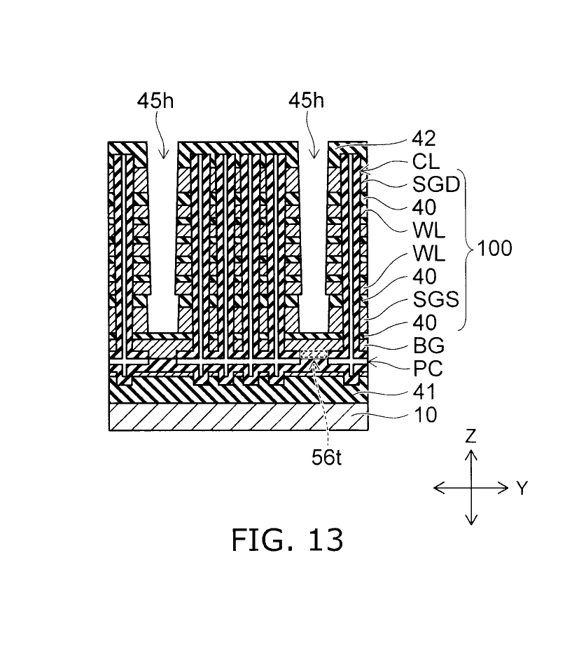

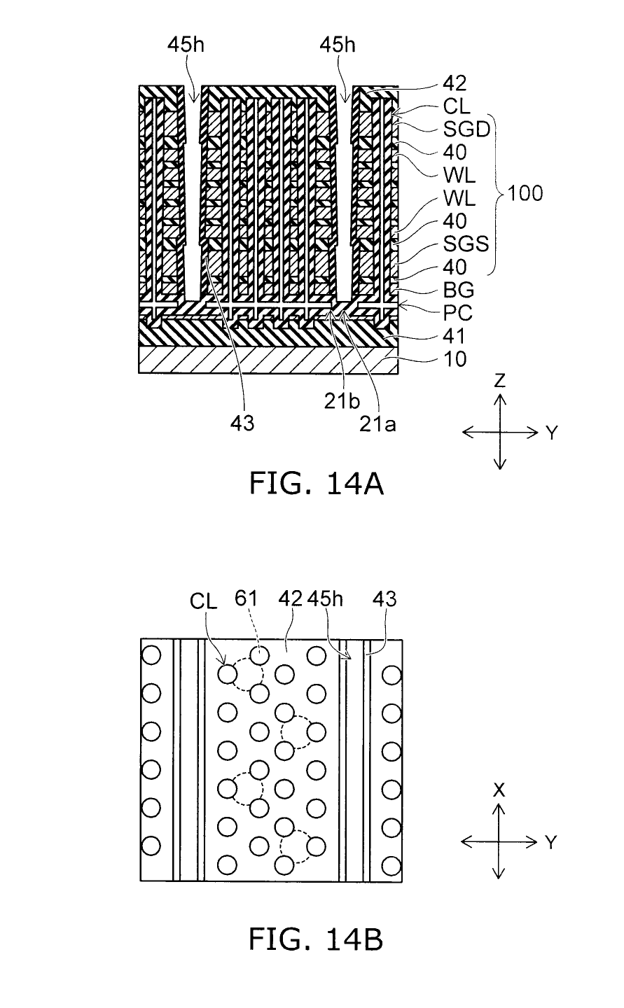

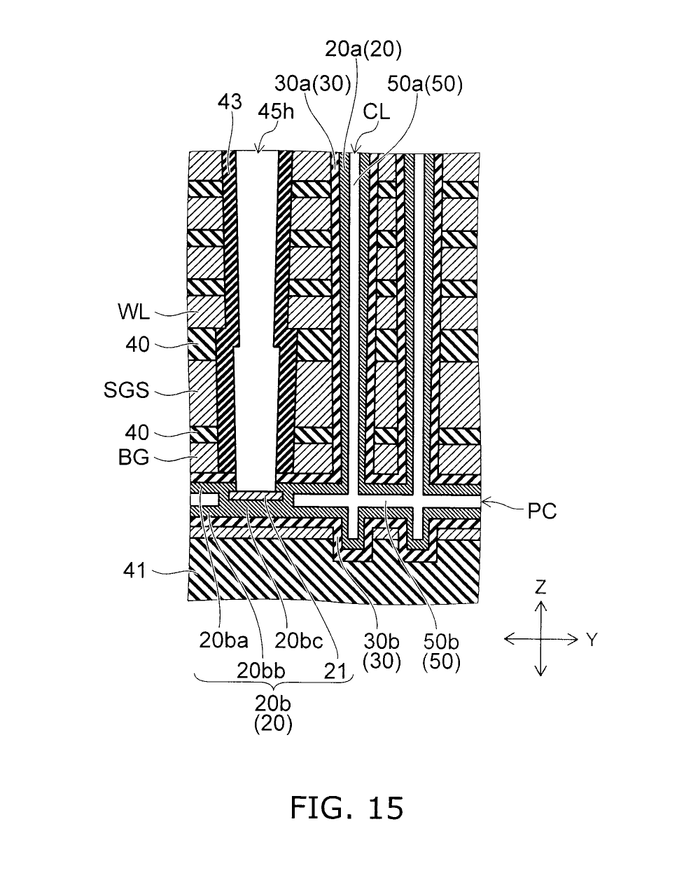

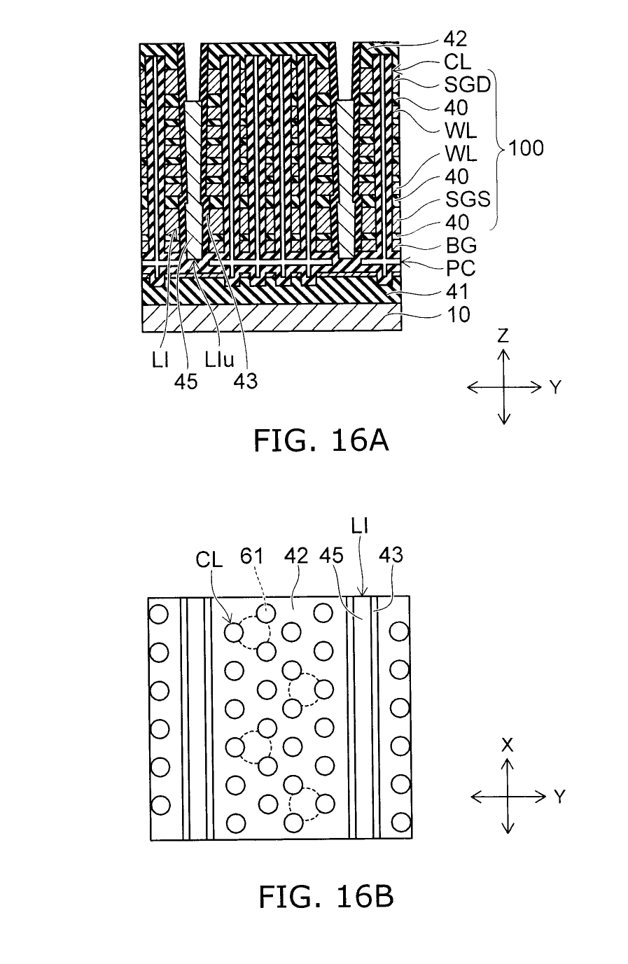

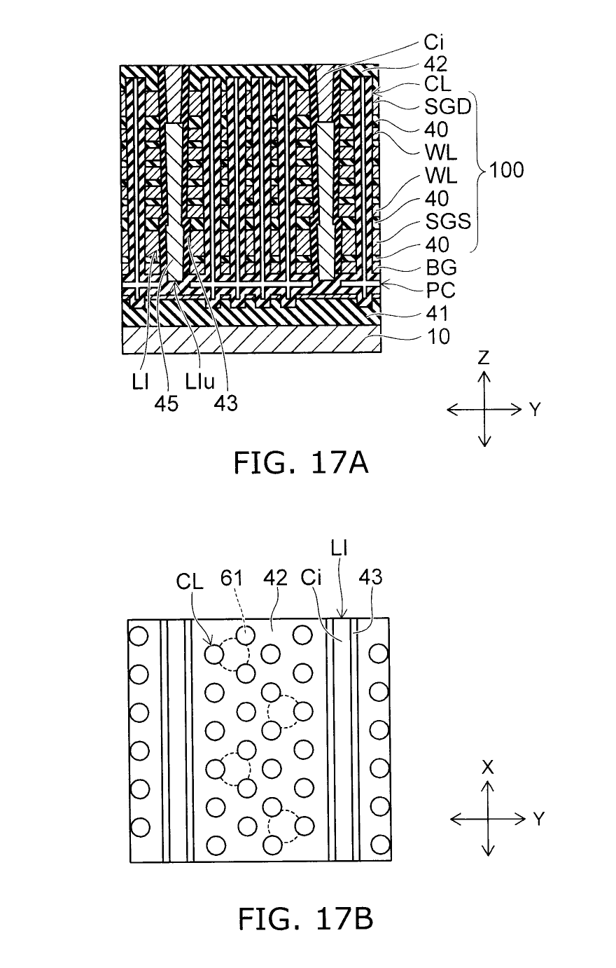

FIG. 5A, FIG. 6A, FIG. 7A, FIG. 8A, FIG. 9A, FIG. 10A, FIG. 11, FIG. 12A, FIG. 13, FIG. 14A, FIG. 15, FIG. 16A and FIG. 17A are schematic sectional views. FIG. 5B, FIG. 6B, FIG. 7B, FIG. 8B, FIG. 9B, FIG. 10B, FIG. 12B, FIG. 14B, FIG. 16B and FIG. 17B are schematic plan views respectively corresponding to the above schematic sectional views.

As shown in FIG. 5A and FIG. 5B, the insulating layer 41 is formed on the substrate 10. The back gate BG is formed on the insulating layer 41.

An upper portion of the back gate BG is removed except for support portions 61, and a sacrifice layer 55 is formed in the removed portion. The sacrifice layer 55 is removed in an after-mentioned process, and the coupling portion PC is formed in the removed portion (replace process). Thus, the stacked body 100 and the like to be formed on the sacrifice layer 55 are supported by the support portions 61. For example, a silicon nitride film is used as the sacrifice layer 55.

As shown in FIG. 6A and FIG. 6B, a resist 56 is formed on the back gate BG and the sacrifice layer 55. Thereafter, part of the resist 56 is removed by using, for example, a PEP method (Photo Engraving Process). The sacrifice layer 55 exposed in the removed portion is removed by using, for example, an RIE method, and opening portions 56h extending in the X-direction are formed.

As shown in FIG. 7A and FIG. 7B, the back gate BG is further formed on the back gate BG, in the opening portions 56h and on the sacrifice layer 55. By this, a protrusion 56t of the back gate BG is formed in the sacrifice layer 55.

As shown in FIG. 8A and FIG. 8B, the source side select gate SGS is formed on the back gate BG via the insulating layer 40, and the insulating layer 40 is formed on the source side select gate SGS. Thereafter, a groove piercing the insulating layer 40, reaching the source side select gate SGS and extending in the X-direction is formed. A sacrifice layer 57 is formed in the groove. The sacrifice layer 57 is formed over the protrusion 56t.

As shown in FIG. 9A and FIG. 9B, the stacked body 100 including the plurality electrode layers WL and the plurality insulating layers 40 is formed on the insulating layer 40 and the sacrifice layer 57. The plurality electrode layers WL is separately stacked each other. The plurality insulating layers 40 is formed between the plurality electrode layers WL. The plurality electrode layers WL and the plurality insulating layers 40 are stacked, for example, alternately one layer by one layer. The drain side select gate SGD is formed in the uppermost layer of the stacked body 100. An insulating layer 42 is formed on the drain side select gate SGD.

Thereafter, memory holes MH piercing the stacked body 100 and reaching the sacrifice layer 55 are formed. The memory holes MH are formed by, for example, the RIE method. The memory holes MH may not pierce the sacrifice layer 55 and have only to reach the sacrifice layer 55.

Thereafter, the sacrifice layer 55 is removed by, for example, wet etching through the memory holes MH. By this, a cavity 55h is formed inside the back gate BG. The cavity 55h is formed integrally with the memory holes MH. The cavity 55h includes the protrusion 56t of the back gate BG. At this time, the support portions 61 support the stacked body 100 and the like.

As shown in FIG. 10A, FIG. 10B and FIG. 11, the respective films (the memory film 30, the film including the channel body 20 and the core insulating portion 50) shown in FIG. 4 are formed in sequence on the inner wall (side wall and bottom portion) of the memory hole MH and on the inner wall of the cavity 55h. Thereafter, the respective films formed on the insulating layer 42 are removed. By this, the columnar portion CL and the coupling portion PC are integrally formed.

As shown in FIG. 11, the memory film 30b and the channel body 20b are formed in a portion, where the protrusion 56t is formed, in the coupling portion PC, and the cavity 55h is closed. Thus, the cavity 55h is separated in the Y-direction via the protrusion 56t. Besides, the core insulating portion 50b is not formed under the protrusion 56t. The core insulating portion 50b is separated in the Y-direction via the channel body 20b.

At this time, a maximum width W3 of the columnar portion CL when viewed, for example, from the Z-direction is larger than a maximum width W4 of the coupling portion PC in the Z-direction. Besides, the maximum width W3 is larger than a maximum width W5 of the portion, where the protrusion 56t is provided, of the coupling portion PC in the Z-direction.

Thereafter, the insulating layer 42 covering the columnar portion CL is further formed.

As shown in FIG. 12A and FIG. 12B, slits 45h piercing the stacked body 100 and reaching the sacrifice layer 57 are formed. For example, the RIE method using a not-shown mask is used as a method of forming the slits 45h. The slits 45h are formed to extend in the X-direction. The sacrifice layer 57 is exposed at the bottom surface of the slit 45h.

As shown in FIG. 13, the sacrifice layer 57 is removed by, for example, wet etching through the slit 45h. At this time, the insulating layer 40 is exposed at the bottom surface of the slit 45h. Thereafter, for example, a silicide process of the electrode layers WL and the respective select gates SGS and SGD may be performed through the slits 45h.

As shown in FIG. 14A, FIG. 14B and FIG. 15, the insulating layer 40 exposed at the bottom surface of the slit 45h is removed, and the slit 45h is formed up to the upper surface of the coupling portion PC. The memory film 30 formed in the coupling portion PC is exposed at the bottom surface of the slit 45h.

Thereafter, the insulating film 43 is formed on the inner wall of the slit 45h. Thereafter, the impurity layer 21 shown in FIG. 15 is formed in the channel body 20b in the coupling portion PC through the slit 45h by, for example, an ion implantation method. The impurity concentration of the impurity layer 21 is higher than the impurity concentration of the channel bodies 20a and 20b. At this time, reaction of the electrode layer WL by the ion implantation can be prevented by the insulating film 43 formed on the side wall of the slit 45h. Besides, control of the impurity concentration is facilitated through the slit 45h.

The bottom surface of the slit 45h is further removed, and the slit 45h reaching the channel body 20b in the coupling portion PC is formed.

As shown in FIG. 16A and FIG. 16B, the conductive film 45 is formed in the slit 45h. By this, the interconnect portion LI including the lower surface LIu in contact with the impurity layer 21 is formed. The interconnect portion LI is electrically connected to the channel body 20 of the columnar portion CL via the lower surface LIu.

As shown in FIG. 17A and FIG. 17B, a contact portion Ci is formed on the interconnect portion LI.

Thereafter, as shown in FIG. 2A, the contact portion Cc is formed on the columnar portion CL, and an interconnection layer and the like are formed. By this, the semiconductor memory device of the embodiment is formed.

Next, effects of the embodiment will be described.

According to the embodiment, the channel body 20b in the coupling portion PC includes the first portion 20ba, the second portion 20bb separated from the first portion 20ba in the stacking direction, and the third portion 20bc in contact with the lower surface LIu. The thickness D3 of the third portion 20bc is thicker than the thickness D1 of the first portion 20ba and the thickness D2 of the second portion 20bb. By this, the film thickness of the channel body 20b can be locally made thick. Thus, when the interconnect portion LI is formed, the groove can be easily formed without piercing the channel body 20b. That is, even when the channel body 20b is made thin with miniaturization of the device, increase in difficulty level of processing can be suppressed.

Besides, according to the embodiment, the interconnect portion LI is formed in the third portion 20bc in which the film thickness of the channel body 20b is thick. Thus, the area of the channel body 20b in contact with the interconnect portion LI can be enlarged. Thus, deterioration of characteristics due to the miniaturization can be suppressed.

Further, the maximum width W3 of the columnar portion CL when viewed from the Z-direction is larger than the maximum width W4 of the coupling portion in the Z-direction. Besides, the maximum width W3 is larger than the maximum width W5 of the portion, where the protrusion 56t is provided, of the coupling portion. By this, when the respective films are formed through the memory hole MH, the channel body 20b can be filled in the portion of the protrusion 56t formed. Besides, after the respective films in the cavity 55h are formed, the respective films in the memory hole MH are formed. That is, the columnar portion CL can be made not to be formed before the coupling portion PC is formed, and the processing is facilitated.

For example, in order to prevent the slit 45h from piercing the coupling portion PC, there is a case where the channel body 20b is uniformly made thick in the coupling portion PC. At this time, such a problem may occur that the channel body 20b is agglomerated (agglomeration) in the coupling portion PC and the channel body is divided.

On the other hand, according to the embodiment, the local thick film portion (the third portion 20bc) can be formed in the coupling portion PC. At this time, the agglomeration or the like of the channel body 20b does not occur. By this, the thick film can be formed which does not cause the defect of the channel body and can prevent the slit 45h from piercing the coupling portion PC.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a substrate;
a conductive layer provided on the substrate;
a stacked body provided on the conductive layer and including a plurality of electrode layers separately stacked each other;
a semiconductor pillar portion provided in the stacked body and extending in a stacking direction of the stacked body;
an interconnect portion provided in the stacked body, extending in the stacking direction and a first direction crossing the stacking direction, and including a lower surface;
a semiconductor portion provided relative to the conductive layer via an insulating film in the conductive layer, provided integrally with the semiconductor pillar portion, and extending in the first direction and a second direction crossing the stacking direction and the first direction, the semiconductor portion includes:
a first portion provided relative to the stacked body via the conductive layer and the insulating film;
a second portion provided between the first portion and the substrate and separated from the first portion in the stacking direction; and
a third portion having a maximum thickness being thicker than a maximum thickness of the first portion and ticker than a maximum thickness of the second portion in the stacking direction, the third portion being in contact with the lower surface; and
an insulating portion provided between the first portion and the second portion.

2. The device according to claim 1, wherein the insulating portion is separated in the second direction via the third portion.

3. The device according to claim 1, wherein the insulating portion is separated from the lower surface of the interconnect portion.

4. The device according to claim 1, wherein the insulating film is separated in the second direction via the interconnect portion.

5. The device according to claim 1, wherein, in the second direction, a maximum length of the interconnect portion is larger than a maximum length of a separated portion of the insulating film separated via the interconnect portion.

6. The device according to claim 1, wherein, in the stacking direction, a maximum thickness of a sum of a thickness of the first portion, a thickness of the second portion and a thickness of the insulating portion is thicker than the maximum thickness of the third portion.

7. The device according to claim 1, wherein the insulating portion is separated from the insulating film.

8. The device according to claim 1, wherein the first portion and the second portion are provided continuously in the second direction via the third portion.

9. The device according to claim 1, wherein
the semiconductor portion includes an impurity layer in contact with the lower surface, and
the interconnect portion is electrically connected to the semiconductor pillar via the impurity layer.

10. The device according to claim 9, wherein an impurity concentration of the impurity layer is higher than an impurity concentration of the semiconductor pillar portion.

11. A semiconductor memory device comprising:
a substrate;
a conductive layer provided on the substrate;
a stacked body provided on the conductive layer and including a plurality of electrode layers separately stacked each other;
a semiconductor pillar portion provided in the stacked body and extending in a stacking direction of the stacked body;
an interconnect portion provided in the stacked body, extending in the stacking direction and a first direction crossing the stacking direction, and including a lower surface;
a semiconductor portion provided relative to the conductive layer via an insulating film in the conductive layer, provided integrally with the semiconductor pillar portion, and being in contact with the lower surface; and
an insulating portion provided inside the semiconductor portion, and separated in the stacking direction and a second direction crossing the first direction via the semiconductor portion.

12. The device according to claim 11, wherein the semiconductor portion is provided between the interconnect portion and the insulating portion.

13. The device according to claim 11, wherein the insulating film is separated in the second direction via the interconnect portion.

14. The device according to claim 11, wherein a maximum thickness, in the stacking direction, of a portion of the semiconductor portion in contact with the lower surface is thinner than a maximum thickness, in the stacking direction, of the semiconductor portion including the insulating portion.

15. The device according to claim 11, wherein, in the stacking direction, a maximum distance between the lower surface and the insulating film is larger than a maximum distance between the insulating portion and the insulating film.

16. The device according to claim 11, wherein the insulating portion is separated from the insulating film.

17. The device according to claim 11, wherein the insulating portion includes an air gap.

18. The device according to claim 11, wherein
the semiconductor portion includes an impurity layer in contact with the lower surface, and
the interconnect portion is electrically connected to the semiconductor pillar via the impurity layer.

19. A method for manufacturing a semiconductor memory device, comprising:
forming a sacrifice layer on a substrate;
forming an opening portion, in the sacrifice layer, extending in a first direction parallel to a major surface of the substrate;
forming a conductive layer on the substrate, on the sacrifice layer and in the opening portion;
forming a stacked body, on the conductive layer, including a plurality of electrode layers stacked to be separated from each other;
forming a hole piercing the stacked body and the conductive layer in a stacking direction of the stacked body and reaching the sacrifice layer;
forming a cavity including a protrusion of the conductive layer formed in the opening portion by removing the sacrifice layer through the hole;
forming a film including a charge storage film on an inner wall of the hole and an inner wall of the cavity;
separating the cavity in a second direction crossing the first direction and the stacking direction via the protrusion by forming a semiconductor portion inside the film including the charge storage film;
forming a slit piercing the stacked body and the protrusion, reaching the semiconductor portion and extending in the first direction; and
forming a conductive film in contact with the semiconductor portion in the slit.

20. The method according to claim 19, further comprising forming an insulating portion inside the semiconductor portion, the insulating portion separated in the second direction via the semiconductor portion.
